(19) United States
(12) Patent Application Publication
(10) Pub. No.: US 2025/0062167 A1
(43) Pub. Date: Feb. 20, 2025

(54) SEMICONDUCTOR PACKAGES INCLUDING DAM STRUCTURES

(71) Applicant: SAMSUNG ELECTRONICS CO., LTD., SUWON-SI (KR)

(72) Inventor: Hansae Lim, Suwon-si (KR)

(21) Appl. No.: 18/731,445

(22) Filed: Jun. 3, 2024

(30) Foreign Application Priority Data
Aug. 16, 2023 (KR) 10-2023-0106741

(51) Int. Cl. H01L 23/13; H01L 23/00; H01L 23/16; H01L 23/31; H01L 23/498

(52) U.S. Cl. CPC H01L 23/13; H01L 23/16; H01L 23/3107; H01L 23/49838; H01L 24/16; H01L 2224/16227; H01L 2924/15151

(57) ABSTRACT

A semiconductor package includes a substrate including lower pads and a vent hole, a semiconductor chip, an encapsulant including a through-portion filling the vent hole and an extension disposed adjacent to the through-portion, and a ground plate and a power plate disposed on a lower surface of the substrate. The lower surface of the substrate includes a first region including the vent hole, a pad region including the lower pads, and a second region between the first region and the pad region. The extension extends in a first horizontal direction in the first region. The ground plate and the power plate include at least one first protrusion disposed in the second region and extending in the first horizontal direction and at least one second protrusion extending in an opposite direction, respectively. The at least one first protrusion is disposed to engage with the at least one second protrusion.

### CROSS-REFERENCE TO RELATED APPLICATION

This U.S. non-provisional patent application claims priority under 35 U.S.C. § 119 to Korean Patent Application No. 10-2023-0106741 filed on Aug. 16, 2023 in the Korean Intellectual Property Office (KIPO), the disclosure of which is incorporated by reference herein in its entirety.

### TECHNICAL FIELD

The present inventive concept relates generally to a semiconductor package, and more specifically to a semiconductor package including a dam structure.

### DISCUSSION OF THE RELATED ART

As the demand for high performance, high speed, and/or multifunctionality of semiconductor devices has grown, the degree of integration of semiconductor devices has increased. When manufacturing fine-patterned semiconductor devices in response to the recent trend for high integration of semiconductor devices, it is desirable to implement patterns with fine widths and/or fine distances.

### SUMMARY

One or more embodiments of the inventive concept provide a semiconductor package including a dam structure surrounding a vent hole. A ground plate and a power plate forming a dam structure are disposed on a lower surface of a substrate and are spaced apart from each other with a gap region therebetween.

According to an embodiment of the inventive concept, a semiconductor package includes a substrate including a plurality of lower pads and a vent hole, a semiconductor chip disposed on the substrate, an encapsulant covering the substrate and the semiconductor chip and including a through-portion filling the vent hole and an extension disposed adjacent to the through-portion, and a ground plate and a power plate disposed on a lower surface of the substrate. The lower surface of the substrate includes a first region including the vent hole, a pad region including the plurality of lower pads, and a second region between the first region and the pad region. The extension extends in a first horizontal direction in the first region. The ground plate includes at least one first protrusion disposed in the second region and extending in the first horizontal direction. The power plate includes at least one second protrusion disposed in the second region and extending in a direction that is opposite to the first horizontal direction. The at least one first protrusion is disposed to engage with the at least one second protrusion.

According to an embodiment of the inventive concept, a horizontal width of the at least one first protrusion is about 8 μm to about 25 μm.

According to an embodiment of the inventive concept, the at least one first protrusion is disposed alternately with the at least one second protrusion in a second horizontal direction, intersecting with the first horizontal direction.

According to an embodiment of the inventive concept, the ground plate further includes at least one first depression overlapping the at least one second protrusion in the first horizontal direction. The power plate further includes at least one second depression overlapping the at least one first protrusion in the first horizontal direction.

According to an embodiment of the inventive concept, the lower surface of the substrate includes a first gap region between the ground plate and the power plate.

According to an embodiment of the inventive concept, the first gap region extends in a zigzag pattern along the at least one first protrusion and the at least one second protrusion.

According to an embodiment of the inventive concept, a horizontal width of the first gap region is about 25 μm to about 30 μm.

According to an embodiment of the inventive concept, the lower pads include a power pad. The power plate extends to the pad region such that the power plate is connected to the power pad.

According to an embodiment of the inventive concept, the extension of the encapsulant is positioned to extend between the ground plate and the power plate in the second region.

According to an embodiment of the inventive concept, the at least one second protrusion includes a plurality of second protrusions. A length of a second protrusion disposed relatively close to the first region, among the plurality of second protrusions, is greater than a length of a second protrusion relatively far from the first region, among the plurality of second protrusions.

According to an embodiment of the inventive concept, the lower pads include a first signal pad disposed inside the power plate and a second signal pad disposed inside the ground plate. The lower surface of the substrate further includes a conductive interconnection extending to the first region and the second region and connecting the first signal pad and the second signal pad.

According to an embodiment of the inventive concept, the lower surface of the substrate further includes a second gap region formed within the power plate and a third gap region between the ground plate and the power plate. The conductive interconnection is disposed in the second gap region and the third gap region.

According to an embodiment of the inventive concept, a horizontal width of the second gap region is about 50 μm to about 60 μm.

According to an embodiment of the inventive concept, the lower pads include a first signal pad and a second signal pad that are disposed inside the ground plate. The lower surface of the substrate further includes a conductive interconnection extending to the first region and the second region and connecting the first signal pad and the second signal pad.

According to an embodiment of the inventive concept, the pad region includes a first pad region and a second pad region spaced apart from each other with the first region interposed therebetween. The lower pads include a first power pad disposed in the first pad region and a second power pad disposed in the second pad region. The power plate extends to the second pad region through the first pad region, the second region, and the first region to connect the first power pad and the second power pad.

According to an embodiment of the inventive concept, the ground plate is located inside the power plate and is surrounded by the power plate and the extension.

According to an embodiment of the inventive concept, a semiconductor package includes a substrate including a plurality of lower pads and a vent hole, a semiconductor chip disposed on the substrate, and a first conductive plate and a second conductive plate disposed on a lower surface of the substrate. The lower surface of the substrate includes a first region including the vent hole, a pad region including the plurality of lower pads, and a second region between the first region and the pad region. The first conductive plate and the second conductive plate extend in a first horizontal direction in the second region and form a dam structure surrounding the first region. The first conductive plate includes at least one first protrusion disposed in the second region and extending in the first horizontal direction. The second conductive plate includes at least one second protrusion disposed in the second region and extending in a direction that is opposite to the first horizontal direction. The at least one first protrusion is disposed to engage with the at least one second protrusion.

According to an embodiment of the inventive concept, the first conductive plate extends to the pad region to be connected to at least one of the lower pads. The second conductive plate extends to the pad region to be connected to at least one of the lower pads.

According to an embodiment of the inventive concept, a horizontal width of the second region is about 150 μm to about 200 μm.

According to an embodiment of the inventive concept, a semiconductor package includes a substrate including a base insulating layer, a plurality of lower pads disposed on a lower surface of the base insulating layer, a lower passivation layer covering the plurality of lower pads, and a vent hole penetrating through the base insulating layer vertically, a semiconductor chip disposed on the substrate, an encapsulant covering the substrate and the semiconductor chip and including a through-portion filling the vent hole and an extension disposed below the through-portion, and a ground plate and a power plate disposed on a lower surface of the substrate and spaced apart from each other with a gap region therebetween. The lower surface of the substrate includes a first region including the vent hole, a pad region including the plurality of lower pads, and a second region between the first region and the pad region. The extension extends in a first horizontal direction in the first region. The ground plate includes at least one first protrusion disposed in the second region and extending in the first horizontal direction. The power plate includes at least one second protrusion disposed in the second region and extending in a direction that is opposite to the first horizontal direction The at least one first protrusion is disposed to engage with the at least one second protrusion.

### BRIEF DESCRIPTION OF THE DRAWINGS

The above and other features of the inventive concept will become more apparent by describing in detail exemplary embodiments thereof with reference to the accompanying drawings, in which:

FIG. 1 is a vertical cross-sectional view of a semiconductor package along I-I′ as illustrated in FIG. 2 according to embodiments of the inventive concept.

FIG. 2 is a plan view of a semiconductor package according to embodiments of the inventive concept.

FIG. 3 is an enlarged view of a marked area “A” of the semiconductor package illustrated in FIG. 2.

FIG. 4 is a vertical cross-sectional view of the semiconductor package along II-II′ as illustrated in FIG. 3.

FIGS. 5 to 10 are plan views of semiconductor packages according to embodiments of the inventive concept.

FIG. 11 is a plan view of a semiconductor package according to embodiments of the inventive concept.

FIG. 12 is an enlarged view of the semiconductor package as illustrated in FIG. 11.

FIG. 13 is a plan view of a semiconductor package according to embodiments of the inventive concept.

FIG. 14 is a plan view of a semiconductor package according to embodiments of the inventive concept.

FIG. 15 is an enlarged view of the semiconductor package as illustrated in FIG. 14.

### DETAILED DESCRIPTION OF THE EMBODIMENTS

Herein, it will be understood that when an element or layer is referred to as being “on”, “connected to” or “coupled to” another element or layer, it can be directly on, connected or coupled to the other element or layer, or intervening elements or layers may be present.

Like reference numerals may refer to like elements throughout this specification. In the figures, the thicknesses of layers, films or regions may be exaggerated for clarity. The term “and/or” includes any and all combinations of one or more of the associated listed items.

It will be understood that although the terms such as “first” and “second” are used herein to describe various elements, these elements should not necessarily be limited by these terms. The terms are only used to distinguish one component from other components. For example, a first element referred to as a first element in one embodiment may be referred to as a second element in another embodiment without departing from the scope of the appended claims. As used herein, the singular forms, “a”, “an” and “the” are intended to include the plural forms as well, unless the context clearly indicates otherwise.

Also, “under”, “below”, “above”, “upper”, and the like are used for explaining relational association of components or elements illustrated in the drawings. The terms are intended to be a relative concept and are described based on directions as illustrated in the drawings.

Hereinafter, example embodiments of the inventive concept will be described in detail with reference to the accompanying drawings.

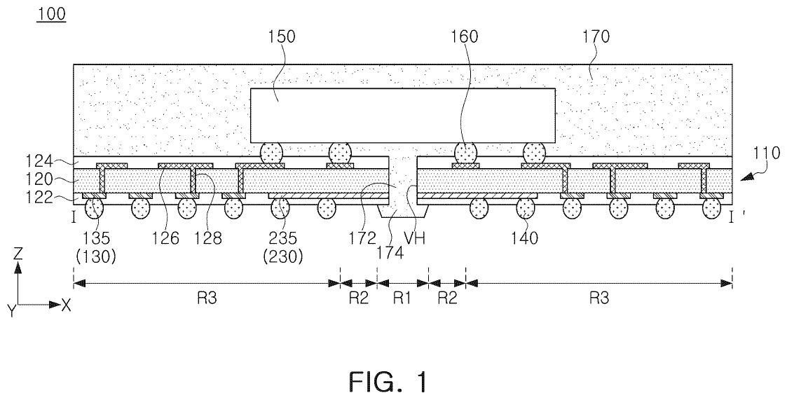

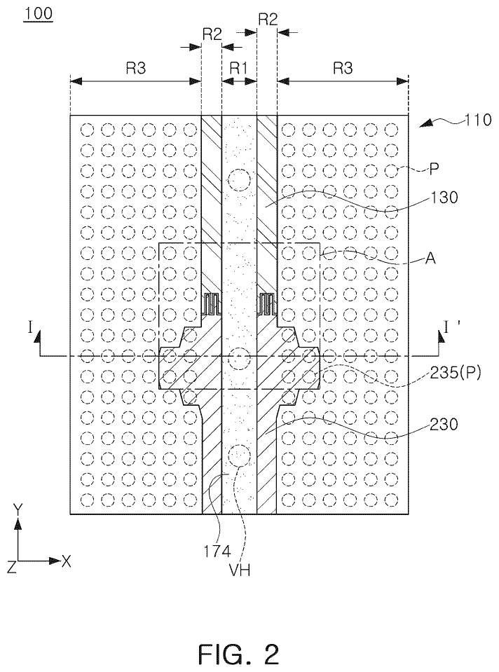

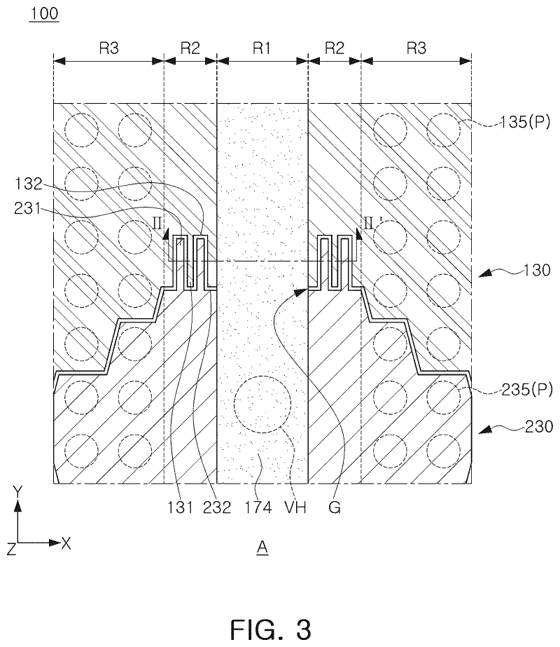

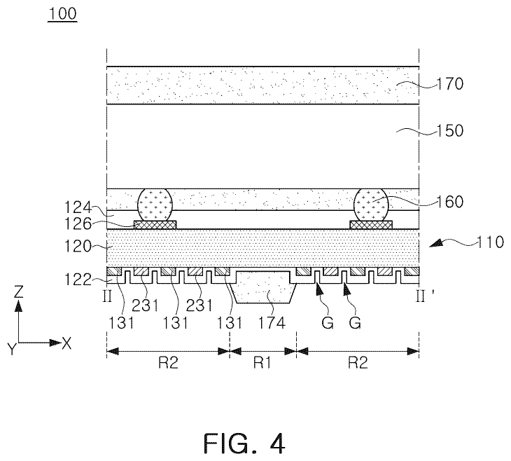

FIG. 1 is a vertical cross-sectional view of a semiconductor package according to some embodiments of the inventive concept. FIG. 2 is a plan view of a semiconductor package according to some embodiments of the inventive concept. FIG. 1 corresponds to a vertical cross-sectional view taken along line I-I′ of the semiconductor package illustrated in FIG. 2. FIG. 3 is an enlarged view of a marked area “A” of the semiconductor package illustrated in FIG. 2. FIG. 4 is a vertical cross-sectional view of the semiconductor package illustrated in FIG. 3. FIG. 1 corresponds to a vertical cross-sectional view taken along line II-II′ of the semiconductor package illustrated in FIG. 2.

Referring to FIGS. 1 to 4, a semiconductor package 100, according to an embodiment of the present disclosure, may include a substrate 110, an external connection terminal 140, a semiconductor chip 150, a chip connection terminal 160, and an encapsulant 170.

The substrate 110 includes a base insulating layer 120, a lower passivation layer 122, an upper passivation layer 124, an upper pad 126, a via 128, a ground plate 130, and a power plate 230. The upper passivation layer 124 is disposed on base insulating layer 120, which is disposed on the lower passivation layer 122. In an embodiment, the substrate 110 may be a substrate for a semiconductor package, such as a printed circuit board (PCB), an interposer substrate, a ceramic substrate, or a tape interconnection board. In an embodiment, the substrate 110 may be a PCB. For example, the base insulating layer 120 of the substrate 110 may include a thermosetting resin, such as an epoxy resin, a thermoplastic resin, such as a polyimide, or a photosensitive insulating layer. In some examples, the base insulating layer 120 may include materials, such as prepreg, Ajinomoto build-up film (ABF), FR-4, bismaleimide triazine (BT), and photo imageable dielectric resin (PID). Embodiments of the inventive concept are not limited to the aforementioned materials.

The lower passivation layer 122 and the upper passivation layer 124 may cover lower and upper surfaces of the base insulating layer 120, respectively. The lower passivation layer 122 and the upper passivation layer 124 may include an insulating resin and an inorganic filler, but may exclude glass fiber. For example, the lower passivation layer 122 and the upper passivation layer 124 may include ABF, but are not limited thereto, and the lower passivation layer 122 and the upper passivation layer 124 may include a photosensitive insulating material (PID) or an insulating polymer, for example, photosensitive polyimide (PSPI).

The upper pad 126 may be disposed on an upper surface of the base insulating layer 120. For example, the upper pad 126 may be covered by the upper passivation layer 124. The vias 128 may penetrate through the base insulating layer 120 vertically and the vias 128 may be connected to the upper pads 126. For example, each via 128 of the vias may be connected to at least one of the upper pads 126.

The ground plate 130 and the power plate 230 may be disposed on the lower surface of the base insulating layer 120. The ground plate 130 and the power plate 230 may be disposed adjacent to the base insulating layer 120. For example, the ground plate 130 and the power plate 230 may be covered by the lower passivation layer 122. Each via 128 may be in contact with at least one of the ground plate 130 and the power plate 230. At least one of the ground plate 130 and the power plate 230 may be electrically connected to the upper pad 126 through the via 128.

According to an embodiment of the inventive concept, the upper pad 126, the via 128, the ground plate 130, and the power plate 230 may include conductive materials, such as copper (Cu), aluminum (Al), silver (Ag), tin (Sn), gold (Au), nickel (Ni), lead (Pb), titanium (Ti), chromium (Cr), tungsten (W), or alloys thereof. In an embodiment, the upper pad 126, the via 128, the ground plate 130, and the power plate 230 may include copper (Cu).

The external connection terminal 140 may be disposed on the lower surface of the substrate 110. The external connection terminal 140 may be in contact with the ground plate 130 and the power plate 230 which are disposed on the lower surface of the substrate 110. A portion of the ground plate 130 in contact with the external connection terminals 140 may be referred to as a ground pad 135, and a portion of the power plate 230 in contact with the external connection terminals 140 may be referred to as a power pad 235. Hence, in FIG. 1, the reference label is named 135 (130) and 235 (230), respectively. A ground voltage Vss may be applied to the ground pad 135, and a power supply voltage Vdd may be applied to the power pad 235. The lower passivation layer 122 may include an opening in a portion corresponding to the ground pad 135 and the power pad 235, and the ground pad 135 and the power pad 235 exposed by the opening may be in contact with the external connection terminal 140. The external connection terminal 140 may be electrically connected to the upper pad 126 through at least one of the ground plate 130 and the power plate 230. The external connection terminal 140 may be electrically connected to an external device, such as a main board. When describing embodiments disclosed in the present specification, the ground plate 130 and the power plate 230 may also be referred to as a first conductive plate and a second conductive plate, respectively.

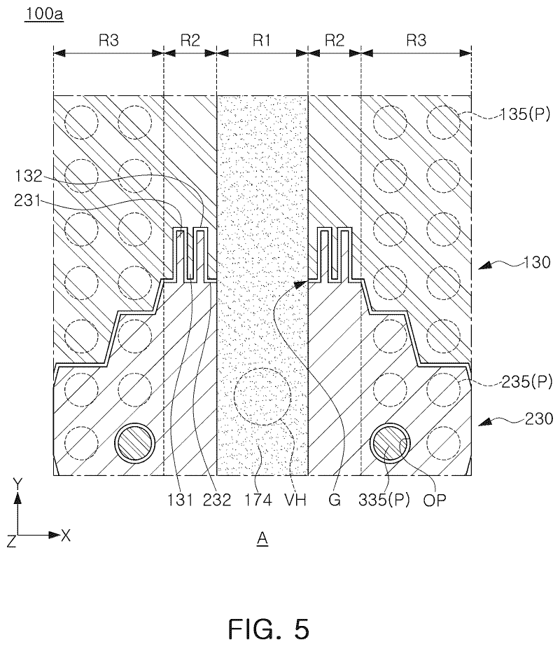

In some embodiments, the semiconductor package 100 may further include a signal pad 335 (with reference to FIGS. 5, 9, and 10). In the descriptions of the present specification, the ground pad 135, the power pad 235, and the signal pad 335 disposed on the lower surface of the substrate 110 may be collectively referred to as lower pads P. The lower pads P might not be completely covered by the lower passivation layer 122 and may be exposed through openings in the lower passivation layer 122.

The semiconductor chip 150 may be mounted on the substrate 110. In an embodiment, the semiconductor chip 150 may be electrically connected to the substrate 110 by the chip connection terminal 160. The semiconductor chip 150 may be covered by the encapsulant 170. For example, the chip connection terminal 160 may have a flip-chip connection structure having a solder ball, a conductive bump, or a grid array, such as a pin grid array, a ball grid array, or a land grid array. The semiconductor chip 150 may include a chip pad disposed on a lower surface thereof. The chip connection terminal 160 may connect the chip pad to the upper pad 126 disposed on the base insulating layer 120.

The chip connection terminal 160 may include at least one of copper (Cu), nickel (Ni), tin (Sn), and an alloy including tin (Sn—Ag). For example, the chip connection terminal 160 may include a pillar portion and a solder portion below the pillar portion. The pillar portion may include at least one of copper (Cu) and nickel (Ni), and the solder portion may include an alloy comprising tin (Sn—Ag).

The semiconductor chip 150 may be a logic chip or a memory chip. The logic chip may include a microprocessor, an analog element, or a digital signal processor. The memory chip may include a volatile memory chip, such as dynamic random access memory (DRAM) or static random access memory (SRAM) or a non-volatile memory chip, such as phase-change random access memory (PRAM), magnetoresistive random access memory (MRAM), ferroelectric random access memory (FeRAM), or resistive random access memory (RRAM).

The encapsulant 170 may cover the substrate 110 and the semiconductor chip 150. The encapsulant 170 may be a resin including epoxy or polyimide. For example, the resin may include a bisphenol-group epoxy resin, a polycyclic aromatic epoxy resin, an o-Cresol Novolac epoxy resin, a biphenyl-group epoxy resin, or naphthalene-group epoxy resin.

In an embodiment, the encapsulant 170 may include a through-portion 172 extending vertically through the substrate 110 and an extension 174 disposed adjacent to the through-portion 172 and extending onto the lower surface of the substrate 110. Referring to FIG. 1, the extension 174 can be viewed as being disposed underneath the through-portion 172. For example, the substrate 110 may include a vent hole VH formed at the center. The vent hole VH may expose side surfaces of the base insulating layer 120, the lower passivation layer 122, and the upper passivation layer 124. The through-portion 172 may be located within the vent hole VH and the through-portion 172 may be in contact with side surfaces of the base insulating layer 120, the lower passivation layer 122, and the upper passivation layer 124. The encapsulant 170 includes the through-portion 172 filling the vent hole VH and the extension 174 is disposed below the through-portion 172. The extension 174 may be located underneath the through-portion 172 and may protrude downwardly relative to the lower passivation layer 122. A level of a lower surface of the extension 174 is lower than a level of a lower surface of the lower passivation layer 122. In the semiconductor package 100 as described in some embodiments of the present disclosure, since the encapsulant 170 includes the through-portion 172 and the extension 174, voids may be discharged when the encapsulant 170 is formed, and voids may be prevented from remaining inside the encapsulant 170.

FIG. 2 corresponds to a downward plan view of the substrate 110 illustrated in FIG. 1. Referring to FIG. 2, the lower surface of the substrate 110 may include a first region R1 and a second region R2. The first region R1 may be disposed at the center of the lower surface of the substrate 110 in the X-direction and may extend in the Y-direction. The vent hole VH and the extension 174 of the encapsulant 170 may be disposed in the first region R1. For example, the extension 174 may extend in the Y-direction along the first region R1. The second region R2 may be disposed on a side of the first region R1. For example, one second region R2 is disposed on one side of the first region R1. One second region R2 is disposed on the other side of the first region R1. For example, the second regions R2 may be spaced apart from each other in the X-direction with the first region R1 therebetween. The second region R2 may extend in the Y-direction along the first region R1. The lower surface of the substrate 110 may further include a pad region R3. The pad region R3 may refer to a portion of the lower surface of the substrate 110 other than the first region R1 and the second region R2. Lower pads P may be disposed in the pad region R3. Herein, the ground pad 135, the power pad 235, and the signal pad 335 (as shown in at least FIGS. 1 and 5) and disposed on the lower surface of the substrate 110 may be collectively referred to as lower pads P. For example, the second region R2 may refer to a region disposed between the first region R1 and the pad region R3, in which the lower pads P are not disposed. The second region R2 may exclude lower pads P. A horizontal width of the second region R2 in the X-direction may be about 150 μm to about 200 km.

The ground plate 130 may be disposed in the second region R2. For convenience and brevity of description, just a portion of the ground plate 130 disposed in the second region R2 is illustrated in FIG. 2. In some cases, the ground plate 130 may further extend to the pad region R3 to be connected to the ground pads 135 among the lower pads P.

The power plate 230 may be disposed in the second region R2. In addition, the power plate 230 may further extend to the pad region R3 to be connected to the power pad 235 among the lower pads P. For example, the power plate 230 may be connected to a set of power pads 235 arranged in the pad region R3 and the power plate 230 may fill a space between the power pads 235. Some embodiments of the present disclosure include multiple ground plates 130 and multiple power plates 230. A set of ground plates 130 and a set of power plates 230 may be arranged in the second region R2. In addition, ground plates 130 and power plates 230 may be further arranged in the pad region R3.

The ground plate 130 and the power plate 230 may form a dam structure within the second region R2. For example, a portion of the ground plate 130 and a portion of the power plate 230 may extend in the Y-direction within the second region R2 and may form a dam structure surrounding the first region R1. The dam structure may cover the side surface of the extension 174 of the encapsulant 170 and prevent the extension 174 from flowing into the pad region R3.

Referring to FIG. 3 (an enlarged view of a marked area “A” of the semiconductor package illustrated in FIG. 2), the ground plate 130 may be disposed in the second region R2 and may extend further to the pad region R3 to be connected to the lower pad P. The power plate 230 may be disposed in the second region R2 and may extend further to the pad region R3 to be connected to the lower pad P. As described above, the lower pad P connected to the ground plate 130 and the lower pad P connected to the power plate 230 may be referred to as the ground pad 135 and the power pad 235, respectively. Hence, the reference labels are named as 135(P) and 235(P), respectively, to indicate this aspect.

In an embodiment, the ground plate 130 may include a first protrusion 131 and a first depression 132 disposed in the second region R2, and the power plate 230 may include a second protrusion 231 and a second depression 232 disposed in the second region R2. The first protrusion 131 and the second protrusion 231 may extend in a direction in parallel to the Y-direction, and the first protrusion 131 may extend in a direction opposite to the second protrusion 231. For example, in the plan view illustrated in FIG. 3, the second protrusion 231 may extend in the direction indicated by the Y-directional arrow of the coordinate system between the second depressions 232. The first protrusion 131 may extend in a direction, opposite to the direction in which the second protrusion 231 extends between the first depressions 132. The first protrusion 131 extends downwardly in the Y direction. The second protrusion 231 extends upwardly in the Y direction. The first protrusion 131 and the second protrusion 231 are disposed in parallel to each other. The widths of a set of first protrusions 131 in the X-direction may be equal to each other, and the widths of a set of second protrusions 231 in the X-direction may be equal to each other.

In an embodiment, the ground plate 130 may be arranged to engage with the power plate 230 within the second region R2. For example, the first protrusions 131 of the ground plate 130 may be alternately arranged with the second protrusions 231 of the power plate 230 in the X-direction. The first protrusions 131 of the ground plate 130 may overlap the second depressions 232 of the power plate 230 in the Y-direction. The second protrusions 231 of the power plate 230 may overlap the first depressions 132 of the ground plate 130 in the Y-direction. The ground plate 130 may be spaced apart from the power plate 230 and may not be electrically connected. For example, the first protrusion 131 may be spaced apart from the second protrusion 231 and the second depression 232 in the X-direction and the Y-direction, respectively, and the first depression 132 may be spaced apart from the second protrusion 231 and the second depression 232 in the Y-direction and the X-direction, respectively. The horizontal widths of the first protrusion 131 and the second protrusion 231 in the X-direction may be about 8 m to about 25 m.

In an embodiment, one or more first protrusions of the ground plate 130 are disposed in the second region R2 and extend in a first horizontal direction (e.g., downward Y direction). One or more second protrusions of the power plate 230 are disposed in the second R2 region and extend in a direction opposite to the Y direction (e.g., upward Y direction). At least one first protrusion of the ground plate 130 may engage with at least one second protrusion of the power plate 230.

In FIG. 3, a space between the ground plate 130 and the power plate 230 may be referred to as a gap region G. For example, the lower surface of the substrate 110 may include the gap region G disposed between the ground plate 130 and the power plate 230 within the second region R2. The gap region G may extend in a zigzag pattern along the first protrusion 131, the first depression 132, the second protrusion 231, and the second depression 232. The horizontal width of the gap region G may be about 25 μm to about 30 μm. Here, the horizontal width of the gap region G may refer to a distance between the first protrusion 131 and the second protrusion 231 adjacent to each other in the X-direction. In some examples, the gap region G may extend further to the pad region R3 (e.g., the gap region G is disposed within the second region R2 and the pad region R3).

According to some embodiments of the present disclosure, since the substrate 110 includes the vent hole VH therein, when forming the encapsulant 170, a portion of the encapsulant 170 may extend to the lower surface of the substrate 110 through the vent hole VH to form the extension 174. Since the ground plate 130 should be spaced apart from the power plate 230 such that the ground plate 130 and the power plate 230 are not to be electrically connected, the gap region G may be disposed between the ground plate 130 and the power plate 230. The gap region G extends in a zigzag pattern along at least one first protrusion (e.g., first protrusion 131) and at least one second protrusion (e.g., second protrusion 231). If both the ground plate 130 and the power plate 230 are disposed in the second region R2 of the lower surface of the substrate 110, the occurrences of having a portion of the encapsulant 170 flow to the pad region R3 from the first region R1 through the gap region G to cover the lower pad P may arise. For example, as illustrated in FIG. 4, which is a cross-sectional view of the semiconductor package along II-II′ as illustrated in FIG. 3, the lower passivation layer 122 may have a groove between the ground plate 130 and the power plate 230, and the encapsulant 170 may flow through the groove.

Referring to FIG. 4, in an embodiment, the first protrusions 131 and the second protrusions 231 are alternately arranged in the X-direction. The first protrusions 131 and the second protrusions 231 are disposed in the second region R2. The lower passivation layer 122 may at least partially cover the first protrusions 131 and second protrusions 231.

Referring to FIGS. 3 and 4, the ground plate 130 (with reference to FIG. 3) includes at least one first depression 132 overlapping at least one second protrusion 231 in a horizontal direction (e.g., the X direction). The power plate 230 includes at least one second depression 232 overlapping at least one first protrusion 131 in the first horizontal direction (e.g., the X direction).

However, according to some embodiments of the present disclosure, the ground plate 130 and the power plate 230 may be arranged to engage with each other and the gap region G may extend in a zigzag pattern. Accordingly, the encapsulant 170 may be prevented from flowing into the pad region R3, and poor contact between the lower pad P and the external connection terminal 140 in a subsequent process of forming the external connection terminal 140 is prevented.

Although not illustrated in plan view, at least one lower pad P may be electrically connected to a corresponding one of the upper pads 126 through the vias 128 illustrated in FIG. 1. An interconnection connecting the lower pad P and the via 128 may be further disposed on the lower surface of the substrate 110.

FIGS. 5 to 10 are various plan views of semiconductor packages according to embodiments of the present disclosure. Referring to FIG. 5 (an enlarged view of area “A”), a semiconductor package 100a may include the ground plate 130 and the power plate 230 disposed on the lower surface of the substrate 110. In an embodiment, the signal pad 335 may be disposed on the lower surface of the substrate 110. For example, the signal pad 335 may be disposed inside the power plate 230. The signal pad 335 may be disposed within the pad region R3. The power plate 230 may include an opening OP exposing the signal pad 335, and the power plate 230 and the signal pad 335 may be spaced apart from each other by the opening OP. Accordingly, the power plate 230 might not be electrically connected to the signal pad 335. The signal pad 335 may be used to transmit data signals DQ, data strobe signals DQS, clock signals Clock, command/address signals CA, etc. to the semiconductor chip 150.

In an embodiment, the gap region G extends in a zigzag pattern along the at least one first protrusion (e.g., first protrusion 131) and at least one second protrusion (e.g., second protrusion 231).

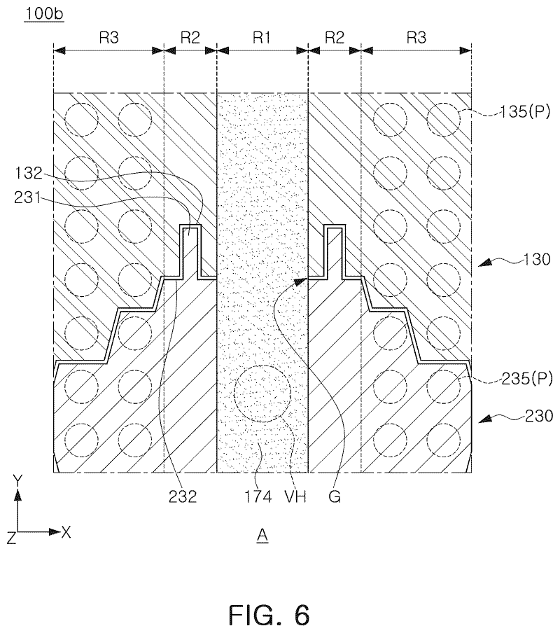

Referring to FIG. 6 (an enlarged view of area “A”), a semiconductor package 100b may include the ground plate 130 and the power plate 230 disposed on the lower surface of the substrate 110. In an embodiment, the power plate 230 may include one second protrusion 231 and second depressions 232 that are disposed on both sides of the second protrusion 231 (e.g., the both sides of the second protrusion 231 are in parallel to the Y direction). The number and shape of the protrusions and depressions illustrated in FIG. 6 are an example for purpose of illustration and embodiments of the inventive concept are not limited thereto. Herein, the ground pad 135, the power pad 235, and the signal pad 335 (if any) disposed on the lower surface of the substrate 110 may be collectively referred to as lower pads P.

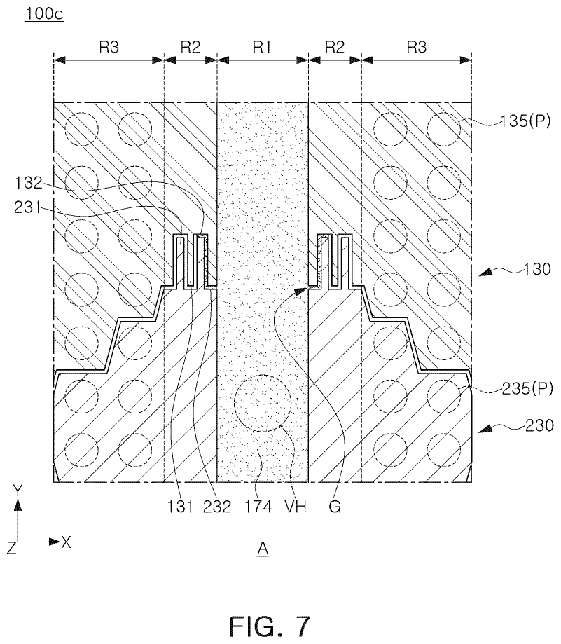

Referring to FIG. 7 (an enlarged view of area “A”), the substrate 110 of a semiconductor package 100c may include the first region R1 and the second region R2 on the lower surface thereof. In an embodiment, the extension 174 of the encapsulant 170 disposed in the first region R1 may extend to the second region R2. For example, when the encapsulant 170 is formed by a transfer molding method, the extension 174 may extend to the second region R2 along the gap region G between the ground plate 130 and the power plate 230. That is, the extension 174 may partially fill the gap region G within the second region R2, and a portion of the extension 174 may be disposed between the ground plate 130 and the power plate 230. However, the extension 174 may not extend to the pad region R3 or be in contact with the lower pad P.

In an embodiment, the set of second protrusions 231 may have same lengths among themselves. For example, the length of the second protrusion 231 relatively close to the first region R1 in the Y-direction, among the set of second protrusions 231, may be the same as the length of the second protrusion 231 relatively far from the first region R1 in the Y-direction, among the set of second protrusions 231.

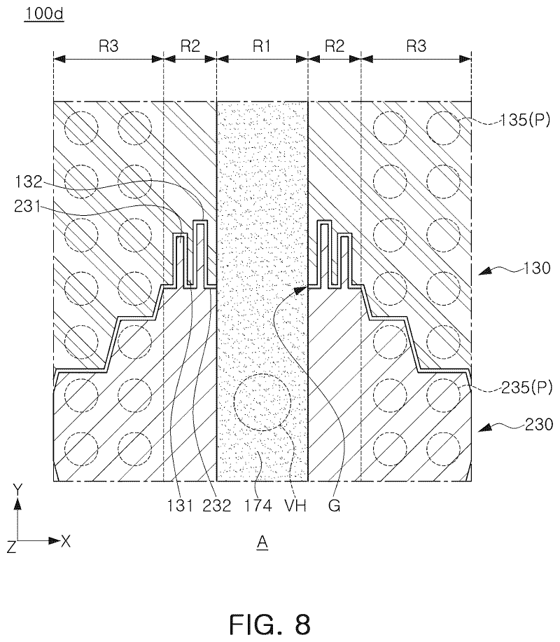

Referring to FIG. 8, a semiconductor package 100d may include the ground plate 130 and the power plate 230 disposed on the lower surface of the substrate 110. In an embodiment, the set of second protrusions 231 may have different lengths among themselves. For example, the length of the second protrusion 231 relatively close to the first region R1 in the Y-direction, among the set of second protrusions 231, may be greater than the length of the second protrusion 231 relatively far from the first region R1 in the Y-direction, among the set of second protrusions 231. Since the second protrusion 231 close to the first region R1 is formed to be longer in length, it may prevent the extension 174 of the encapsulant 170 from flowing into the pad region R3. In addition, the lengths of the set of first protrusions 131 may also be different. For example, the length of the first protrusion 131 relatively closer to the first region R1 in the Y-direction, among the set of first protrusions 131, may be greater than the length of the first protrusion 131 relatively far from the first region T1 in the Y-direction.

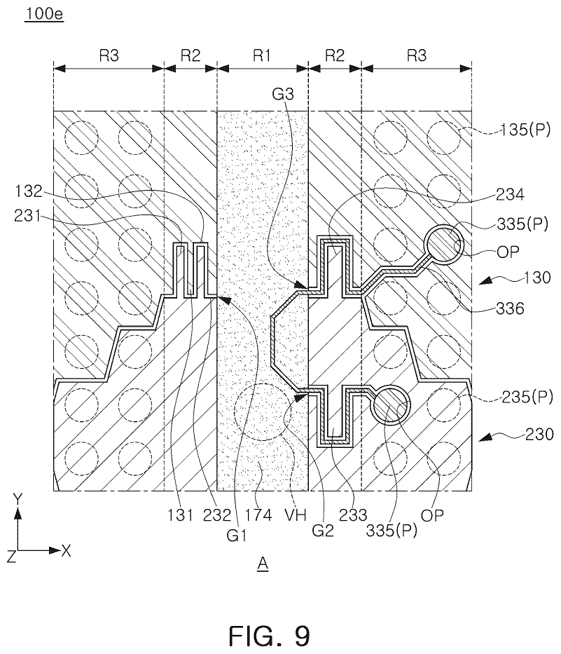

Referring to FIG. 9, a semiconductor package 100e may include the ground plate 130 and the power plate 230 disposed on the lower surface of the substrate 110. In an embodiment, the signal pads 335 may be disposed on the lower surface of the substrate 110. For example, the signal pads 335 may be disposed inside the ground plate 130 and the power plate 230, respectively. In an embodiment, the lower pads P include one or more signal pads 355 disposed inside the power plate 230 and one or more signal pads disposed inside the ground plate 130. The signal pads 335 may be disposed in pad region R3. The ground plate 130 and the power plate 230 may include an opening OP exposing the signal pads 335. The signal pad 335 may be spaced apart from the ground plate 130 and the power plate 230 by the one or more openings OP. Accordingly, the ground plate 130 and the power plate 230 may not be electrically connected to the signal pad 335.

In an embodiment, the signal pads 335 may be connected to each other through a conductive interconnection 336. For example, the conductive interconnection 336 may connect the signal pads 335 to each other through the ground plate 130, the extension 174, and the power plate 230. For example, the conductive interconnection 336 connects a first signal pad disposed inside the power plate 230 and the second signal pad disposed inside the ground plate 130 through extending to the first region R1 and the second region R2. In some cases, the conductive interconnection 336 may be spaced apart from the ground plate 130 and the power plate 230. Accordingly, the conductive interconnection 336 might not be electrically connected to the ground plate 130 or the power plate 230.

For example, the lower surface of the substrate 110 may include a first gap region G1, a second gap region G2, and a third gap region G3, and the conductive interconnection 336 may extend in the horizontal direction within the second gap region G2 and the third gap region G3. The first gap region G1 may include a structure the same as or similar to that of the gap region G described above with reference to FIG. 3. A detailed description of the first gap region G1 may be omitted for brevity.

The second gap region G2 may be formed within the power plate 230. For example, the second gap region G2 may extend in the horizontal direction to connect the signal pad 335 disposed inside the power plate 230 to the first region R1. To prevent the extension 174 from flowing into the pad region R3, the second gap region G2 may extend in a zigzag pattern within the second region R2, and the power plate 230 may include a third protrusion 233 corresponding to the second gap region G2.

The third gap region G3 may be formed between the ground plate 130 and the power plate 230. In some cases, a first portion of the third gap region G3 may be formed in the power plate 230 and a second portion of the third gap region G3 may be formed in the ground plate 130. For example, the third gap region G3 may extend in the horizontal direction to connect the signal pad 335 disposed inside the ground plate 130 to the first region R1. To prevent the extension 174 from flowing into the pad region R3, the third gap region G3 may extend in a zigzag pattern within the second region R2, and the power plate 230 may include a fourth protrusion 234 corresponding to the third gap region G3. The fourth protrusion 234 may protrude in a direction opposite to the third protrusion 233. For example, the fourth protrusion 234 may protrude upwardly in the Y direction. The third protrusion 233 may protrude downwardly in the Y direction.

In an embodiment, the conductive interconnection 336 may also extend to connect the second gap region G2 and the third gap region G3 within the first region R1. A portion of the conductive interconnection 336 disposed in the first region R1 may be covered by the extension 174 of the encapsulant 170.

The width of the conductive interconnection 336 may be about 25 μm to about 30 μm. A distance between the conductive interconnection 336 and the power plate 230 within the second gap region G2 may be about 25 μm to about 30 μm. A distance between the conductive interconnection 336 and the ground plate 130 within the third gap region G3 may be about 25 μm to about 30 μm. Horizontal widths of the second gap region G2 and the third gap region G3 may be greater than the horizontal width of the first gap region G1. For example, the horizontal widths of the second gap region G2 and the third gap region G3 may be about 50 μm to about 60 μm. For example, a horizontal width of the second gap region G2 is about 50 μm to about 60 μm. A horizontal width of the third gap region G3 is about 50 μm to about 60 μm, i.e., same as or similar to the horizontal width of the second gap region G2.

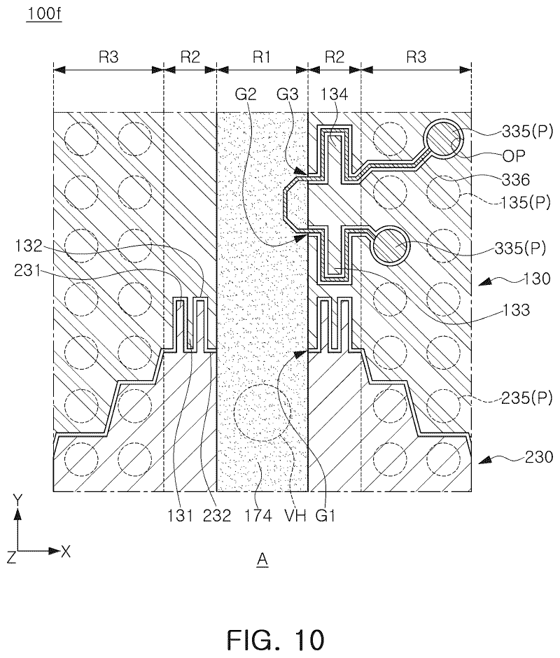

Referring to FIG. 10, a semiconductor package 100f may include the ground plate 130 and the power plate 230 disposed on the lower surface of the substrate 110. In an embodiment, the signal pads 335 may be disposed on the lower surface of the substrate 110. For example, the signal pads 335 may be disposed inside the ground plate 130. The lower surface of the substrate 110 includes the conductive interconnection 336 extending to the first region R1 and the second region R2 such that the conductive interconnection 336 connects the signal pads 335 disposed inside the ground plate 130 (e.g., a first signal pad and a second signal pad are connected). The ground plate 130 may include an opening OP exposing the signal pads 335. The signal pad 335 may be spaced apart from the ground plate 130 by the one or more openings OP, and accordingly the signal pad 335 might not be electrically connected to the ground plate 130.

In an embodiment, the signal pads 335 may be connected to each other through a conductive interconnection 336. For example, the lower surface of the substrate 110 may include the first gap region G1, the second gap region G2, and the third gap region G3, and the conductive interconnection 336 may extend in the horizontal direction within the second gap region G2 and the third gap region G3. The first gap region G1 may include a structure the same as or similar to that of the gap region G described above with reference to FIG. 3.

The second gap region G2 and the third gap region G3 may be formed in the ground plate 130. In an embodiment, the second gap region G2 and the third gap region G3 may extend in the horizontal direction to connect the signal pads 335 disposed inside the ground plate 130 to the first region R1. Horizontal widths of the second gap region G2 and the third gap region G3 may be greater than the horizontal width of the first gap region G1. To prevent the extension 174 from flowing into the pad region R3, the second gap region G2 and the third gap region G3 may extend in a zigzag pattern within the second region R2, and the ground plate 130 may include a third protrusion 133 and a fourth protrusion 134 corresponding to the second gap region G2 and the third gap region G3. The fourth protrusion 234 may protrude in a direction opposite to the third protrusion 233. For example, the fourth protrusion 234 may protrude upwardly in the Y direction. The third protrusion 233 may protrude downwardly in the Y direction.

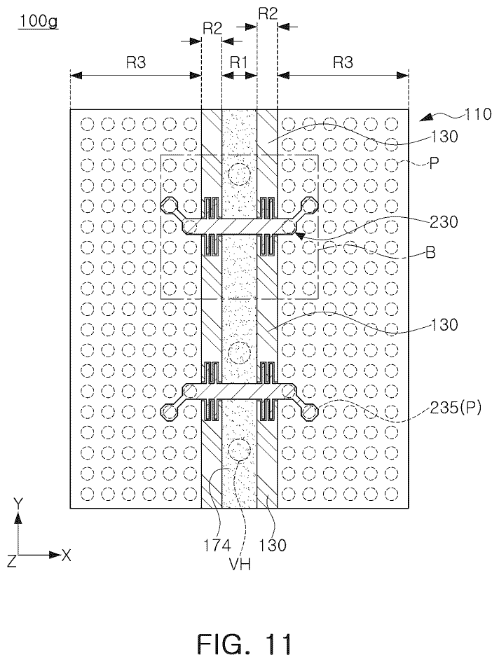

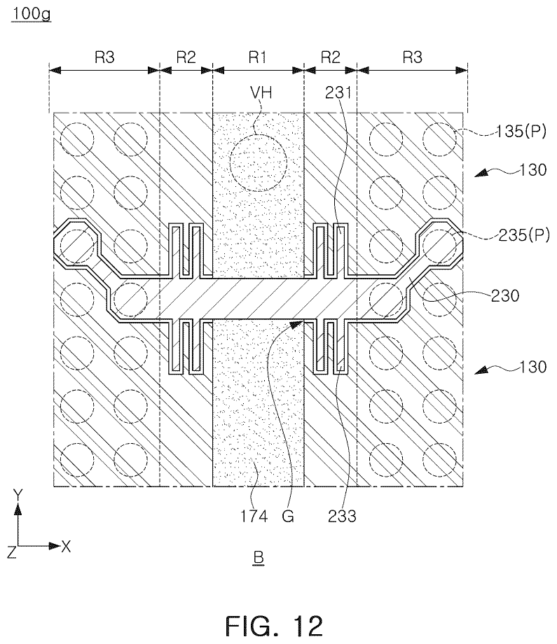

FIG. 11 is a plan view of a semiconductor package according to example embodiments. FIG. 12 is an enlarged view of the marked areas “B” of the semiconductor package as illustrated in FIG. 11. Referring to FIGS. 11 and 12, a semiconductor package 100g may include power plates 230 disposed between the ground plates 130. As illustrated in FIG. 11, the ground plates 130 are illustrated to be spaced apart from each other, however in some embodiments, the ground plates 130 may be connected to each other within the pad region R3. The power plate 230 may connect the power pads 235, spaced apart from each other in the X-direction with the first region R1 therebetween, to each other. For example, a portion of the power plate 230 may extend in the X-direction within the first region R1. A portion of the power plate 230 may be disposed in the first region R1, and the portion of the power plate 230 (disposed in the first region R1) may be covered by the extension 174 of the encapsulant 170.

In an embodiment, the power plate 230 may include a set of protrusions extending in the Y-direction within the second region R2. For example, the power plate 230 may include a second protrusion 231 extending in the Y-direction and a third protrusion 233 extending in a direction, opposite to the second protrusion 231. For example, the second protrusion 231 may protrude upwardly in the Y direction. The third protrusion 233 may protrude downwardly in the Y direction. In an embodiment, the power plate 230 may include a set of second protrusions 231 extending in the Y-direction and a set of third protrusions 233 extending in a direction, opposite to the second protrusion 231.

In an embodiment, referring to FIG. 11, the pad region R3 includes a first pad region and a second pad region spaced apart from each other with the first region R1 interposed therebetween. For example, the first pad region is disposed towards the left of the first region R1. The second pad region is disposed towards the right of the first region R1. The lower pads P include a first power pad disposed in the first pad region and a second power pad disposed in the second pad region. The first power pad is disposed towards the left of the first region R1. The second power pad is disposed towards the right of the first region R1. The power plate 230 extends to the second pad region through the first pad region, the second region, and the first region such that the first power pad is connected to the second power pad.

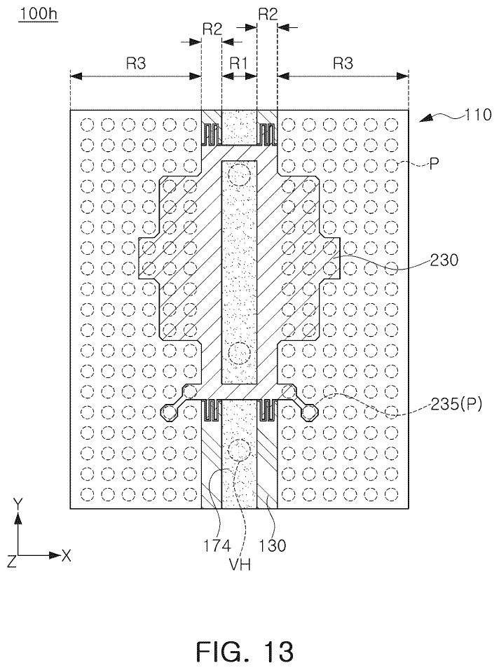

FIG. 13 is a plan view of a semiconductor package according to embodiments of the present disclosure. Referring to FIG. 13, a semiconductor package 100h may include the power plate 230 disposed between the ground plates 130. Similar to the power plate 230 described above with reference to FIGS. 11 and 12, the power plate 230 of the semiconductor package 100h may connect to power pads 235, spaced apart from each other in the X-direction with the first region R1 therebetween, to each other. In addition, like the power plate 230 described above with reference to FIGS. 1 to 4, the power plate 230 may be connected to a set of power pads 235 disposed in the pad region R3 and the power plate 230 may fill a space between the power pads 235.

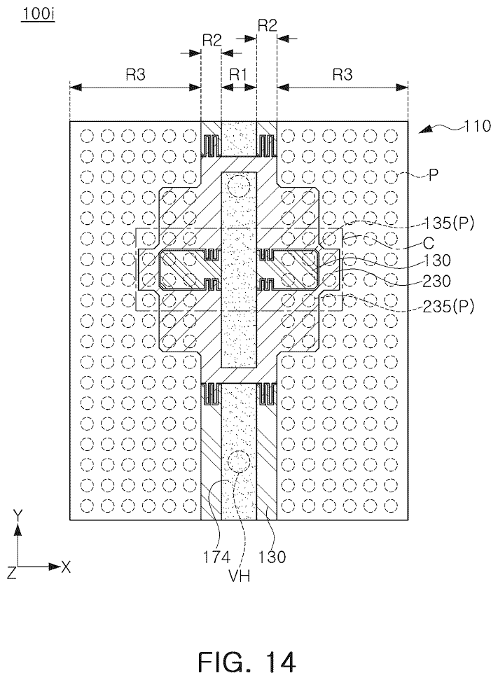

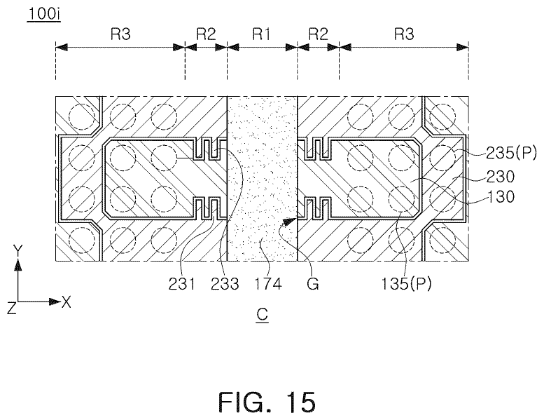

FIG. 14 is a plan view of a semiconductor package according to embodiments of the inventive concepts. FIG. 15 is an enlarged view of the marked area “C” of the semiconductor package as illustrated in FIG. 14. Referring to FIGS. 14 and 15, a semiconductor package 100i may include the ground plate 130 disposed within the power plate 230. For example, at least one ground plate 130 may be surrounded by the extension 174 and the power plate 230. The gap region G may extend in the horizontal direction between the ground plate 130 and the power plate 230 and may extend in a zigzag pattern within the second region R2.

In an embodiment, the power plate 230 may include a set of protrusions extending in the Y-direction within the second region R2. For example, the power plate 230 may include the second protrusion 231 extending in the Y-direction and the third protrusion 233 extending in a direction, opposite to the second protrusion 231. For example, the second protrusion 231 may protrude upwardly in the Y direction. The third protrusion 233 may protrude downwardly in the Y direction. The second protrusion 231 may be disposed to overlap the third protrusion 233 in the Y-direction. That is, the second protrusion 231 and the third protrusion 233 may be spaced apart from each other in the Y-direction with the ground plate 130 interposed therebetween and may extend toward the ground plate 130. As an example, the second protrusion 231 and the third protrusion 233 are disposed within the second region R2.

In some embodiments, a ground plate and a power plate forming a dam structure are disposed on a lower surface of a substrate and are spaced apart from each other with a gap region therebetween. In some examples, the gap region is formed in a zigzag pattern such that an encapsulant is excluded from covering a lower pad. Therefore, the ground plate and the power plate may include a set of protrusions arranged to engage each other.

According to some embodiments of the inventive concept, the lower surface of the substrate of the semiconductor package may include the dam structure surrounding the vent hole. The dam structure may include the conductive plates arranged to engage with each other. Therefore, embodiments of the inventive concept prevent a portion of the encapsulant introduced into the lower surface of the substrate from flowing into the pad region through the vent hole.

While the inventive concept has been particularly shown and described with reference to the exemplary embodiments thereof, it will be understood by one of ordinary skill in the art that variations in form and detail may be made therein without departing from the spirit and scope of the inventive concept.

What is claimed is:

1. A semiconductor package comprising:
a substrate including a plurality of lower pads and a vent hole;
a semiconductor chip disposed on the substrate;
an encapsulant covering the substrate and the semiconductor chip and including a through-portion filling the vent hole and an extension disposed adjacent to the through-portion; and
a ground plate and a power plate disposed on a lower surface of the substrate,
wherein the lower surface of the substrate includes a first region including the vent hole, a pad region including the plurality of lower pads, and a second region between the first region and the pad region,
wherein the extension extends in a first horizontal direction in the first region,
wherein the ground plate includes at least one first protrusion disposed in the second region and extending in the first horizontal direction,
wherein the power plate includes at least one second protrusion disposed in the second region and extending in a direction that is opposite to the first horizontal direction, and
wherein the at least one first protrusion is disposed to engage with the at least one second protrusion.

2. The semiconductor package of claim 1, wherein a horizontal width of the at least one first protrusion is about 8 μm to about 25 μm.

3. The semiconductor package of claim 1, wherein the at least one first protrusion is disposed alternately with the at least one second protrusion in a second horizontal direction, intersecting with the first horizontal direction.

4. The semiconductor package of claim 1, wherein the ground plate further includes at least one first depression overlapping the at least one second protrusion in the first horizontal direction, and
wherein the power plate further includes at least one second depression overlapping the at least one first protrusion in the first horizontal direction.

5. The semiconductor package of claim 1, wherein the lower surface of the substrate includes a first gap region between the ground plate and the power plate.

6. The semiconductor package of claim 5, wherein the first gap region extends in a zigzag pattern along the at least one first protrusion and the at least one second protrusion.

7. The semiconductor package of claim 5, wherein a horizontal width of the first gap region is about 25 μm to about 30 μm.

8. The semiconductor package of claim 1, wherein the plurality of lower pads include a power pad, and
wherein the power plate extends to the pad region such that the power plate is connected to the power pad.

9. The semiconductor package of claim 1, wherein the extension of the encapsulant is positioned to extend between the ground plate and the power plate in the second region.

10. The semiconductor package of claim 1, wherein the at least one second protrusion includes a plurality of second protrusions, and
wherein a length of a second protrusion disposed relatively close to the first region, among the plurality of second protrusions, is greater than a length of a second protrusion disposed relatively far from the first region, among the plurality of second protrusions.

11. The semiconductor package of claim 1, wherein the plurality of lower pads include a first signal pad disposed inside the power plate and a second signal pad disposed inside the ground plate, and
wherein the lower surface of the substrate further includes a conductive interconnection extending to the first region and the second region and connecting the first signal pad and the second signal pad.

12. The semiconductor package of claim 11, wherein the lower surface of the substrate further includes a second gap region formed within the power plate and a third gap region between the ground plate and the power plate, and
wherein the conductive interconnection is disposed in the second gap region and the third gap region.

13. The semiconductor package of claim 12, wherein a horizontal width of the second gap region is about 50 μm to about 60 μm.

14. The semiconductor package of claim 1, wherein the plurality of lower pads include a first signal pad and a second signal pad that are disposed inside the ground plate, and
wherein the lower surface of the substrate further includes a conductive interconnection extending to the first region and the second region and connecting the first signal pad and the second signal pad.

15. The semiconductor package of claim 1, wherein the pad region includes a first pad region and a second pad region spaced apart from each other with the first region interposed therebetween,
wherein the plurality of lower pads include a first power pad disposed in the first pad region and a second power pad disposed in the second pad region, and
wherein the power plate extends to the second pad region through the first pad region, the second region, and the first region to connect the first power pad and the second power pad.

16. The semiconductor package of claim 1, wherein the ground plate is located inside the power plate and is surrounded by the power plate and the extension.

17. A semiconductor package comprising:
A substrate including a plurality of lower pads and a vent hole;
a semiconductor chip disposed on the substrate; and
a first conductive plate and a second conductive plate disposed on a lower surface of the substrate,
wherein the lower surface of the substrate includes a first region including the vent hole, a pad region including the plurality of lower pads, and a second region between the first region and the pad region,
wherein the first conductive plate and the second conductive plate extend in a first horizontal direction in the second region and form a dam structure surrounding the first region,
wherein the first conductive plate includes at least one first protrusion disposed in the second region and extending in the first horizontal direction,
wherein the second conductive plate includes at least one second protrusion disposed in the second region and extending in a direction that is opposite to the first horizontal direction, and
wherein the at least one first protrusion is disposed to engage with the at least one second protrusion.

18. The semiconductor package of claim 17, wherein the first conductive plate extends to the pad region to be connected to at least one of the plurality of lower pads, and
wherein the second conductive plate extends to the pad region to be connected to at least one of the plurality of lower pads.

19. The semiconductor package of claim 17, wherein a horizontal width of the second region is about 150 μm to about 200 μm.

20. A semiconductor package comprising:
a substrate including a base insulating layer, a plurality of lower pads disposed on a lower surface of the base insulating layer, a lower passivation layer covering the plurality of lower pads, and a vent hole penetrating through the base insulating layer vertically;
a semiconductor chip disposed on the substrate;
an encapsulant covering the substrate and the semiconductor chip and including a through-portion filling the vent hole and an extension disposed below the through-portion; and
a ground plate and a power plate disposed on a lower surface of the substrate and spaced apart from each other with a gap region therebetween,
wherein the lower surface of the substrate includes a first region including the vent hole, a pad region including the plurality of lower pads, and a second region between the first region and the pad region,
wherein the extension extends in a first horizontal direction in the first region,
wherein the ground plate includes at least one first protrusion disposed in the second region extending in the first horizontal direction,
wherein the power plate includes at least one second protrusion disposed in the second region and extending in a direction that is opposite to the first horizontal direction, and
wherein the at least one first protrusion is disposed to engage with the at least one second protrusion.
